(19) United States
(12) Patent Application Publication
(10) Pub. No.: US 2025/0107128 A1
(43) Pub. Date: Mar. 27, 2025

(54) Power Semiconductor Device and Method of Producing a Power Semiconductor Device

(71) Applicant: Infineon Technologies AG, Neubiberg (DE)

(72) Inventors: Frank Pfirsch, München (DE); Hans-Joachim Schulze, Taufkirchen (DE); Vera van Treek, Unterhaching (DE)

(21) Appl. No.: 18/895,557

(22) Filed: Sep. 25, 2024

(30) Foreign Application Priority Data
Sep. 26, 2023 (DE) 102023126033.2

(51) Int. Cl. H01L 29/739; H01L 27/07; H01L 29/06; H01L 29/66; H01L 29/866

(52) U.S. Cl. CPC H10D 12/481; H10D 8/25; H10D 12/038; H10D 62/127; H10D 84/811

(57) ABSTRACT

A power semiconductor device includes: a semiconductor body that conducts a load current between first and second load terminals at opposite first and second sides; a drift region of a first conductivity type; trenches extending from the first side towards the second side and each including a trench electrode; mesas laterally confined by the trenches and each including first and second type mesas; and semiconductor structures each including a serial connection of a first region of the first conductivity type coupled to or formed by the drift region, a second region of a second conductivity type and a third region of the first conductivity type coupled to the first load terminal by at least one of a first ohmic resistor and a Zener diode. Each first type mesa is electrically connected to the first load terminal and devoid of the semiconductor structures which are arranged in the second type mesas.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

Irrespective of whether or not the device exhibits an RC configuration, it is generally an aim to design a power semiconductor device such it exhibits a high robustness, i.e., in terms of handling overload situations during which the load current temporarily exceeds the nominal load current, e.g., due to a short circuit situation or the like.

### SUMMARY

According to an embodiment, a power semiconductor device comprises, in a single chip: A semiconductor body configured to conduct a load current between a first load terminal at a first side of the semiconductor body and a second load terminal at a second side of the semiconductor body; a drift region of a first conductivity type within the semiconductor body; trenches extending from the first side towards the second side, each trench including a trench electrode separated from the semiconductor body by a trench insulator; mesas laterally confined by said trenches, wherein the mesas include first type mesas and second type mesas; and semiconductor structures. Each semiconductor structure includes a serial connection of a first region of the first conductivity type coupled to or formed by the drift region; a second region of a second conductivity type; and a third region of the first conductivity type coupled to the first load terminal by at least one of a first ohmic resistor and a Zener diode. Each first type mesa is configured for load current conduction, electrically connected to the first load terminal and devoid of any of said semiconductor structures. The semiconductor structures are arranged in the second type mesas.

According to a further embodiment, a method of producing a power semiconductor device comprises forming, in a single chip, the following components: A semiconductor body configured to conduct a load current between a first load terminal at a first side of the semiconductor body and a second load terminal at a second side of the semiconductor body; a drift region of a first conductivity type within the semiconductor body; trenches extending from the first side towards the second side, each trench including a trench electrode separated from the semiconductor body by a trench insulator; mesas laterally confined by said trenches, wherein the mesas include first type mesas and second type mesas; and semiconductor structures. Each semiconductor structure includes a serial connection of a first region of the first conductivity type coupled to or formed by the drift region; a second region of a second conductivity type; and a third region of the first conductivity type coupled to the first load terminal by at least one of a first ohmic resistor and a Zener diode. Each first type mesa is configured for load current conduction, electrically connected to the first load terminal and devoid of any of said semiconductor structures. The semiconductor structures are arranged in the second type mesas.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a vertical cross-section of a power semiconductor device in accordance with one or more embodiments;

FIG. 2 schematically and exemplarily illustrates a section of a horizontal projection of a power semiconductor device in accordance with one or more embodiments;

FIG. 3 schematically and exemplarily illustrates a section of a vertical cross-section of a power semiconductor device in accordance with one or more embodiments;

FIG. 4 schematically and exemplarily illustrates a section of a horizontal projection of a power semiconductor device in accordance with one or more embodiments;

FIG. 5 schematically and exemplarily illustrates a section of a vertical cross-section of a power semiconductor device in accordance with one or more embodiments;

FIGS. 6A-6C schematically and exemplarily illustrates three sections of a horizontal projection of a power semiconductor device in accordance with some embodiments;

FIG. 7A-9 each schematically and exemplarily illustrate sections of a vertical cross-section of a power semiconductor device in accordance with some embodiments;

FIG. 10-19 each schematically and exemplarily illustrate a section of a horizontal projection of a power semiconductor device in accordance with some embodiments; and

FIG. 20-25C each schematically and exemplarily illustrate sections of a vertical cross-section of a power semiconductor device in accordance with some embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor device is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

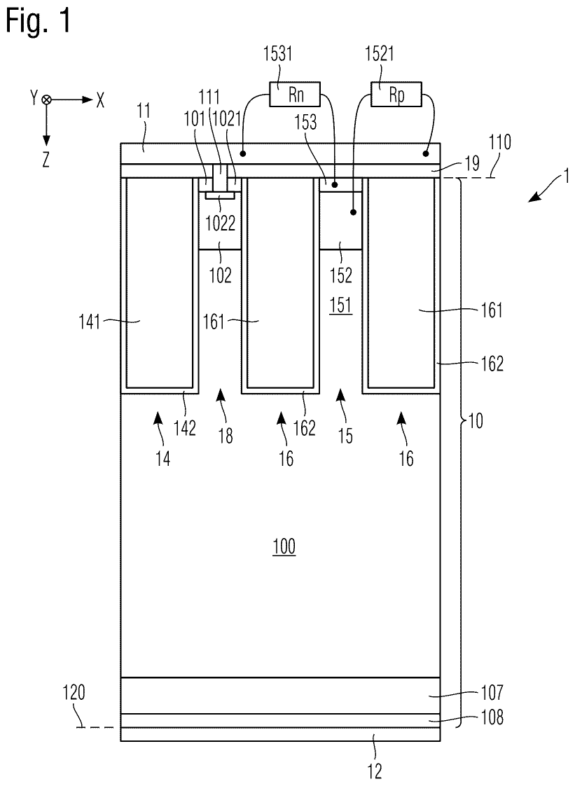

FIG. 1 schematically and exemplarily illustrates a section of a vertical cross-section of a power semiconductor device 1 in accordance with one or more embodiments. The power semiconductor device 1, herein also referred to as “device”, comprises, in a single chip, a semiconductor body 10 configured to conduct a load current between a first load terminal 11 at a first side 110 of the semiconductor body 10 and a second load terminal 12 at a second side 120 of the semiconductor body 10.

The first side 110 and the second side 120 may be arranged opposite of each other. For example, the first side 110 is a front side of the device 1 and the second side 120 is a back side of the device 1. Accordingly, the device 1 may exhibit a vertical configuration according to which the load current within the device 1 follows a path in parallel to the vertical direction Z.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities of the device 1.

The device 1 further comprises trenches 14, 16 extending from the first side 110 towards the second side 120, e.g., along the vertical direction Z. Each trench 14, 16 includes a trench electrode 141, 161 separated from the semiconductor body 10 by a trench insulator 142, 162.

Said trenches may include first type trenches 14, wherein each trench electrode 141 of the first type trenches 14 is electrically insulated from the first load terminal 11 and configured to receive a control signal. To this end, each trench electrode 141 of the first type trenches 14 is electrically connected to a (non-illustrated) control terminal of the device 1, in accordance with an embodiment. Herein, the first type trenches 14 are also referred to as “control trenches” and the corresponding trench electrodes 141 as “control trench electrodes”.

Said trenches may further include second type trenches 16, wherein each trench electrode 161 of the second type trenches 16 is electrically connected to the first load terminal 11. Herein, the second type trenches 16 are also referred to as “source trenches” and the corresponding trench electrodes 161 as “source trench electrodes”.

The device 1 further comprises mesas 15, 18 laterally confined by said trenches 14, 16. The mesas 15, 18 include first type mesas 18 and second type mesas 15.

For example, each first type mesa 18 is laterally confined by at least one of the control trenches 14. For example, each first type mesa 18 is electrically connected to the first load terminal 11, e.g., by means of a respective first contact plug 111 as illustrated. Alternatively, a planar contact may be employed. Each first type mesa 18 may be configured for load current conduction. For example, each first type mesa 18 comprises a semiconductor body region 102 of the second conductivity type electrically connected to the first load terminal 11 (e.g., by said first contact plug) and, optionally, a semiconductor source region 101 of the first conductivity type electrically connected to the first load terminal 11, wherein the semiconductor source region 101 is isolated from the drift region 100 by at least the semiconductor body region 102. The adjacent control trench electrode 141 may be configured to induce, upon being subject with a corresponding ON-control signal, an inversion channel in the semiconductor body region 102. This process may set the device 1 into the forward conducting state. The adjacent control trench electrode 141 may be configured to cut off, upon being subject with a corresponding OFF-control signal, said inversion channel in the semiconductor body region 102, which can set the device 1 into the forward blocking state.

A first body contact region 1021 and a second body contact region 1022 exhibiting an increased dopant concentration compared to the average dopant concentration of the body region 102 may be formed as subportions of the body region 102 and arranged in contact with the first contact plug 111.

The configuration of the second type mesas 15 may be different as compared to the configuration of the first type mesas 18. For example, the second type mesas 15 are not configured for load current conduction during nominal operating conditions of the device 1, which will be explained in more detail below.

The above described features of the power semiconductor device 1 may allow designing diverse trench-mesa-patterns at the first side 110. Such pattern may include further trench types and/or further mesa types, e.g., floating trenches whose trench electrodes are not connected with a defined electrical potential, or second type control trenches whose trench electrodes are connected to a different control terminal as compared to the control trench electrodes 141 to implement a dual or multi gate configuration and so on. Also other type mesas may be implemented, e.g., those having a different threshold voltage as compared to the first type mesas 18. The following description of the embodiments focuses on the trench-mesa-patterns employing the first and the second trenches 14, 16 and the first and second type mesas 15, 18, wherein presence of further type trenches and/or further type mesas is not excluded unless explicitly stated.

The portion of the semiconductor body 10 adjoining the second load terminal 12 at the second side 120 can be configured in accordance with the designated characteristic of the device 1. For example, an emitter region 108 of the second conductivity type may be provided between the drift region 100 and the second load terminal 12, if the device 1 shall exhibit an IGBT configuration. The emitter region 108 is arranged in contact with the second load terminal 12. Furthermore, a field stop region 107 of the first conductivity type can be provided between the drift region 100 and the second load terminal 12, wherein the field stop region 107 exhibits a greater dopant concentration than the drift region 100. If the device 1 shall exhibit a MOSFET configuration, the emitter region 108 is omitted such that the field stop region 107 would adjoin the second load terminal 12. If the device 1 shall exhibit an RC IGBT configuration, the emitter region 108 may exhibit subsections of the first conductivity type, as it is known to the skilled person.

To minimize conduction and switching losses, a power semiconductor device (as the device 1 described above) may be designed with a comparatively small total vertical extension of the semiconductor body. If turned off, i.e., when switching from the forward conduction state into the forward blocking state, in particular in an overload situation where the forward load current is above the nominal load current, dynamically increased field strengths may come into being. Such dynamically increased field strengths may be caused by the hole current flowing in the space charge zone, which due to the positive charge of the holes leads to an increased space charge density compared to the static case. A possible consequence can be the occurrence of a so-called dynamic avalanche, in which many electron-hole pairs are generated by impact ionization. Then, when a turn-off of the device is performed, unstable states are run through, during which a filamentation of the load current can occur. In such a filament of the load current, the load current density can be more than an order of magnitude higher than the average overall current density. Then the device can be destroyed for example by latch-up. The risk of such latch-up increases with reduced device thickness.

Herein, the overload situation typically is present if the forward load current amounts to at least 150% or 200% of the nominal load current of the device 1.

The embodiments described below exhibit a feature for avoiding the occurrence of dynamic avalanches.

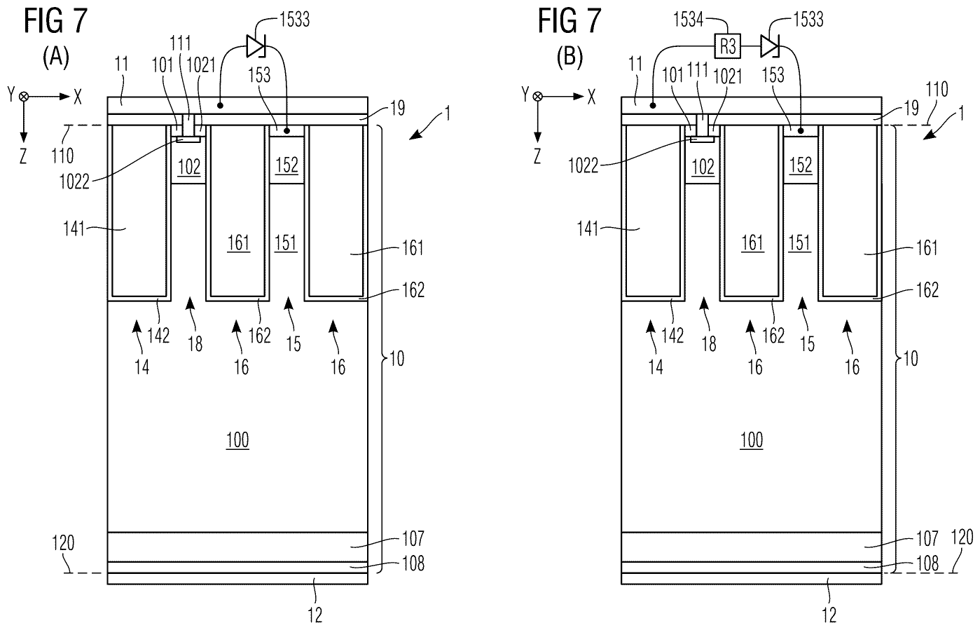

For example, the device 1 further includes semiconductor structures. Each semiconductor structure includes a serial connection of a first region 151 of the first conductivity type coupled to or formed by the drift region 100, a second region 152 of a second conductivity type, and a third region 153 of the first conductivity type coupled to the first load terminal 11 by at least one of a first ohmic resistor 1531 (cf., e.g., FIG. 1, resistor “Rn”) and a Zener diode 1533 (cf., e.g., FIG. 7). Accordingly, the semiconductor structures may be npn semiconductor structures.

Each first type mesa 18 is configured for load current conduction, electrically connected to the first load terminal 11 and devoid of any of said semiconductor structures. The semiconductor structures are arranged in the second type mesas 15.

In an embodiment, the semiconductor structures (cf. elements 151, 152, 153) are configured to inject electrons into the semiconductor body 10 during an overload situation to limit the strength of an electric field in the semiconductor body 10. It may further be provided that the semiconductor structures are configured not to inject a significant amount of electrons into the semiconductor body if the load current is equal to or less than the nominal load current of the power semiconductor device 1, i.e., when there is no overload situation.

The integration of such structures as described above may yield that, during switching the device 1 from the forward conduction state to the forward blocking state in case of an overload situation, even during cut-off of said inversion channel in the first type mesas 18 electrons are injected by said structures. These electrons compensate at least partially the holes present in the space charge region. Accordingly, the increase of the field strengths is limited and the risk of dynamic avalanche is reduced.

In an embodiment, each second type mesa 15 is laterally confined by at least one of the source trenches 16. Furthermore, as illustrated in FIG. 1, it can be ensured that each second type mesa 15 is laterally confined by none of the control trenches 14. That is, the semiconductor structures mentioned above which are included in the second type mesas are arranged in a comparatively high distance to the next control trench electrode 141.

For example, the semiconductor structures are effective only during turn-off of an overload current but otherwise do not or not significantly affect the characteristics of the device 1.

The first region 151 may be formed by the portion of the drift region present within the second type mesa 15. The first region 151 may act as n-collector. The second region 152 may form a p-basis of the semiconductor structure. The second region 152 may be sandwiched between the first region 151 and the third region 153. The third region 153 may act as n-emitter of the structure.

For example, each of the semiconductor structures exhibits a vertical configuration according to which said serial connection of the first region 151, the second region 152 and the third region 153 is established along a direction pointing from the second side 120 to the first side 110, as exemplarily illustrated in FIG. 1. As described above, each of the first region 151, the second region 152 and the third region 153 of each semiconductor structure may be arranged within a respective one of the second type mesas 15. In an embodiment, the third region 153 is arranged in contact with an insulation layer 19 that is arranged between the first load terminal 11 and the semiconductor body 10. At its upper surface, the second region 152 may adjoin a lower surface of the third region 153 to form a first pn-junction. At its lower surface, the second region 152 may adjoin an upper surface of the first region 151 to form a second pn-junction. For example, each of the first region 151, the second region 152 and the third region 153 exhibits a respective width along the first lateral direction X identical to the width of the second type mesa 15. Along the second lateral direction Y, the semiconductor structures, i.e., the respective first region 151, the respective second region 152 and the respective third region 153 may be structured, as will be described further below. The second regions 152 in the second type mesas 15 and the body regions 102 in the first type mesas 18 may be jointly produced, e.g., based on the same processing steps. Likewise, the third regions 153 in the second type mesas 15 and the source regions 101 in the first type mesas 18 may be jointly produced, e.g., based on the same processing steps.

Still referring to FIG. 1, in an embodiment, the second region 152 of at least one or of each of the semiconductor structures is coupled to the first load terminal 11 by at least a second ohmic resistor 1521 (cf., e.g., FIG. 1, resistor “Rp”). In FIG. 1, both the first ohmic resistor 1531 and the second ohmic resistor 1521 are illustrated based on the circuit symbol for an ohmic resistor. In contrast to this schematic illustration, said resistors 1531, 1521 (and similar resistors mentioned below) may be integrated within the chip, e.g., at least partially between the first load terminal 11 and the semiconductor body 10, or e.g. within the semiconductor body 10. Diverse elements may be employed to form and dimension (in terms of ohmic resistance) said resistors 1531, 1521. For example, both the first ohmic resistor 1531 and the second ohmic resistor 1521 are integrated within the single chip and in proximity to the respective structure 151, 152, 153. For example, both the first ohmic resistor 1531 and the second ohmic resistor 1521 are fully or at least partially integrated within one or more of the second type mesas 15.

During turn-off of the device 1, a significant part of the load current flows as hole current to the first side 110. A portion thereof leads into the body region 102 and thus directly to first load terminal 11. The rest of the hole current flows into the second region 152 and further via the second ohmic resistor 1521 to the first load terminal 11. If the voltage drop at the second ohmic resistor 1521 exceeds the diode threshold of the pn-junction between the third region 153 and the second region 152, the third region 153 starts to inject electrons. These electrons diffuse through the second region 152 to the drift region 100 and hence into the space charge zone. There, the electrons flow in the high electric field strength region to the second side 120. In the high electric field strength region of the space charge zone, electrons and holes flow with a velocity that is close to their respective saturation velocity. Hence their concentrations are approximately proportional to the respective current densities. The injected electron current thus leads to a negative contribution to the space charge density and compensates at least in part the positive contribution made by the charge of the holes. Due to the diminished total space charge density a reduced gradient of the electric field and an accordingly reduced maximum field strength is achieved.

Thus, with suitable dimensioning of the first ohmic resistor 1531 and the second ohmic resistor 1521 (examples given below), the risk of dynamic avalanche caused by impact ionization is reduced. The voltage between the second region 152 and the third region 153 depends only slightly (e.g., only logarithmically) on the injected electron current as soon as an injection threshold is exceeded. Thus, the increase of the voltage drops across the first ohmic resistor 1531 and the second ohmic resistor 1521 are about the same as the increase of the corresponding currents. Therefore, the ratio of the ohmic resistance of the first ohmic resistor 1531 and the ohmic resistance of the second ohmic resistor 1521 also determines the ratio of the electron current to the increase of the hole current from the space charge zone into the second region 152. Thus, by dimensioning the ohmic resistance of the first ohmic resistor 1531 and the ohmic resistance of the second ohmic resistor 1521, the degree of charge compensation in the space charge zone can be adjusted.

Regarding the embodiments where the third region 153 is coupled to the first load terminal 11 via at least said first ohmic resistor 1531, one or more of the following dimensioning rules (i) to (v) may apply:
(i) The resistance Rn of said first ohmic resistor 1531 is within the range of 0.2 to 2 times the resistance Rp of said second ohmic resistor 1521.
(ii) The resistance Rn of said first ohmic resistor 1531 is within the range of 40% to 100% of the resistance Rp of said second ohmic resistor 1521.
(iii) The parallel connection of all second ohmic resistors 1521 exhibits a product of active area times resistance, Rp*Aact, within the range of 1 mOhmcm² to 0.1 Ohmcm².
(iv) The parallel connection of all second ohmic resistors 1521 exhibits a product of active area times resistance, Rp*Aact, within the range of 5 mOhmcm² to 20 Ohmcm².
(v) Dimensioning rules (iii) and (iv) may be suitable in case of the device 1 having a nominal load current density in the range of 200 A/cm². If the nominal current density jnom deviates significantly from 200 A/cm², the values given in rules (iii) and (iv) should be scaled anti-proportionally to the nominal current density. For example, Rp*Aact is then between 0.2 V/jnom and 20 V/jnom or between 1 V/jnom and 4 V/jnom. These values apply at room temperature and can vary depending on the temperature, e.g., increase slightly with higher temperature.

With respect to the formation of the first ohmic resistor 1531 and the second ohmic resistor 1521, a few examples will now be described referring to the next Figures. Generally, the first ohmic resistor 1531 and the second ohmic resistor 1521 can be integrated into the chip close to the associated semiconductor structure 151, 152, 153. For a large number of semiconductor structure 151, 152, 153 also a correspondingly large number of distributed resistance structures based the first ohmic resistors 1531 and the second ohmic resistors 1521 may be provided.

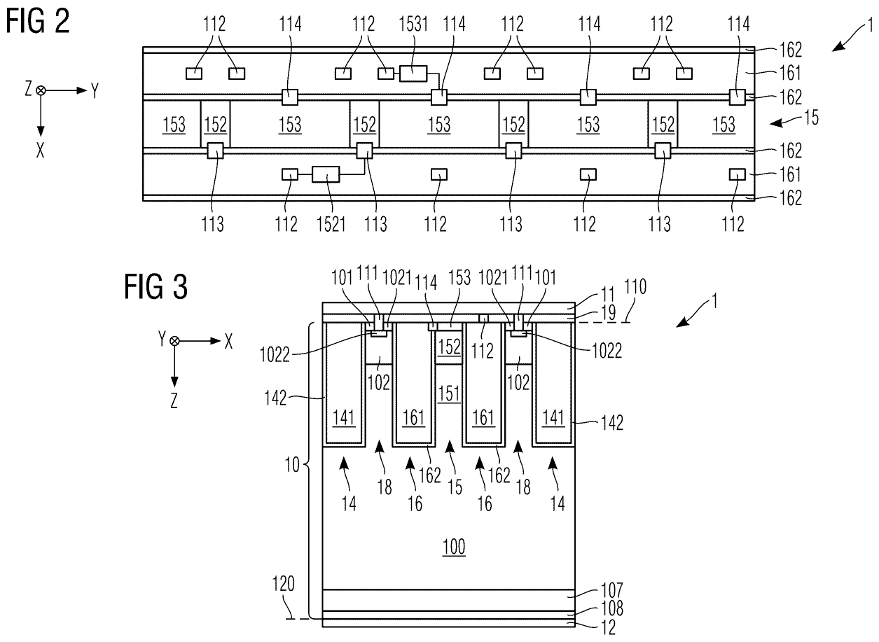

One way to integrate the first ohmic resistors 1531 and the second ohmic resistors 1521 is using the polysilicon filling of adjacent trenches and to arrange the resistors in the third dimension (i.e., along the second lateral direction Y). An example of such variant is illustrated in FIGS. 2 and 3, to which it will now be referred to. There, second contact plugs 112 are employed to electrically connect the source trench electrodes 161 with the first load terminal 11. As illustrated in FIG. 2, the semiconductor structure 151, 152, 153 in the second type mesa 15 is laterally structured along the second lateral direction Y in that the third region 153 is partially omitted along the second lateral direction Y, thereby yielding that in case of omission, the second region 152 adjoins the insulation layer 19. Thereby, both the second region 152 and the third region 153 can be ohmically coupled to the first load terminal 11, e.g., as follows:

As exemplarily illustrated in FIGS. 2 and 3, a first contact bridge 114 may be arranged between the insulation layer 19 and the trench insulator 162 of the source trench 16 such that the first contact bridge 114 connects the third region 153 with the source trench electrode 161 which is electrically connected with the first load terminal 11. Thereby, the first ohmic resistor 1531 is formed between the third region 153 and the first load terminal 11.

Similarly, a second contact bridge 113 may be arranged between the insulation layer 19 and the trench insulator 162 of another one of the source trenches 16 such that the second contact bridge 113 connects the second region 152 with the source trench electrode 161 of the other source trench 16, which is electrically connected with the first load terminal 11. Thereby, the second ohmic resistor 1521 is formed between the second region 152 and the first load terminal 11.

Accordingly, to dimension the resistance of first ohmic resistor 1531 and the resistance of the second ohmic resistor 1521, the resistance of the source trench electrode 161 (which, e.g., is based on polysilicon filling) may be adjusted.

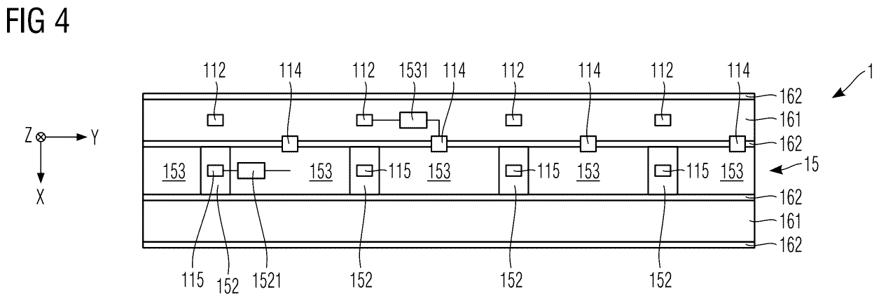

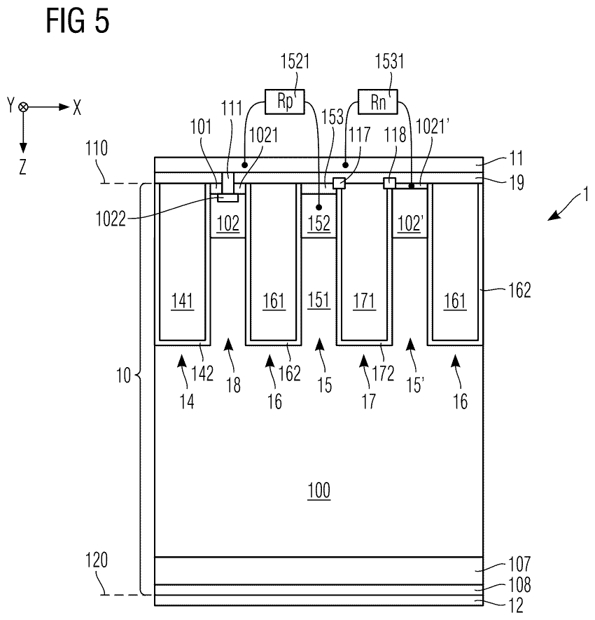

Instead of the second contact bridges 113, the second region 152 may be electrically coupled with the first load terminal 11 based on third contact plugs 115, as illustrated in FIG. 4. For example, the third contact plugs 115 may be configured, in terms of dimension, similar to the first contact plugs 114 employed for electrically connecting the first type mesas 18 with the first load terminal, but with a higher resistance so as to form the second resistors 1521. In an embodiment, also the third region 153 may be contacted based on such contact plugs instead of based on the first contact bridges 114.

FIG. 5 illustrates a vertical cross-section of a further embodiment. For example, in a third type mesa 15′, there is arranged a second body region 102′ of the second conductivity type. The second body region 102′ may comprise a highly doped subportion 1021′. The third type mesa 15′ is arranged separately from the second type mesa 15. For example, mesas 15 and 15′ are separated from each other via a third type trench 17 that includes a trench electrode 171 insulated from the semiconductor body 10 by a trench insulator 172. The third region 153 is electrically connected to the trench electrode 171 of the third type trench 17 via a third contact bridge 117. The second body region 102′ or, respectively, its optional highly doped subportion 1021′, is electrically connected to the trench electrode 171 of the third type trench 17 via a fourth contact bridge 118. The trench electrode 171 of the third type trench 17 may or may not be connected to the first load terminal 11 via a separate contact plug. Furthermore, the second body region 102′ or, respectively, its optional highly doped subportion 1021′, is electrically connected to the first load terminal 11, in accordance with an embodiment, e.g., via a fourth contact plug 116. Accordingly, in an example, the first ohmic resistance 1531 (Rn) may be formed based on the third contact bridge 117, the trench electrode 171 of the third type trench 17, the fourth contact bridge 118 and the second body region 102′.

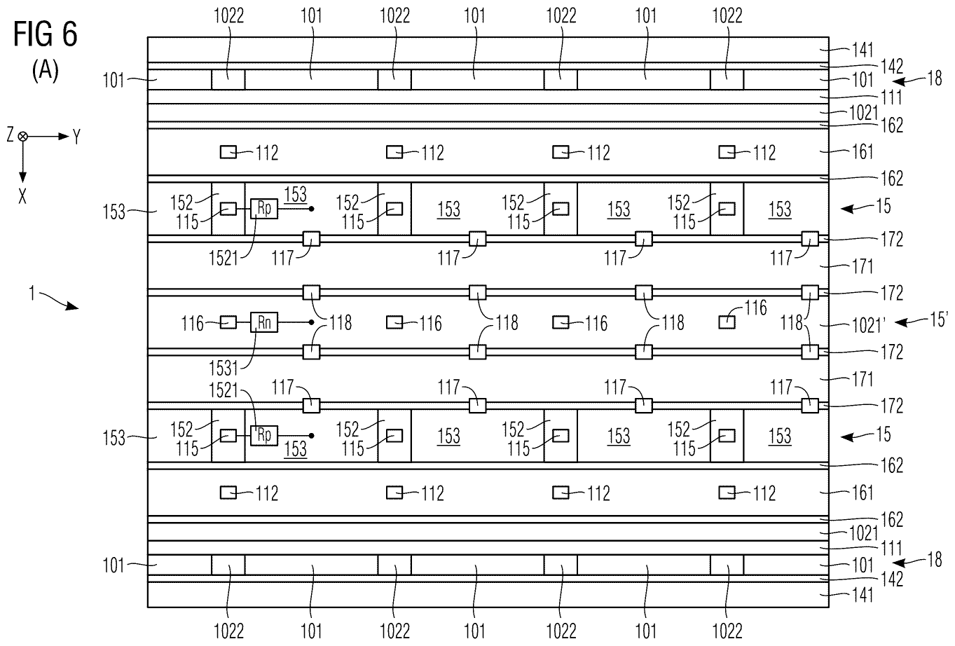

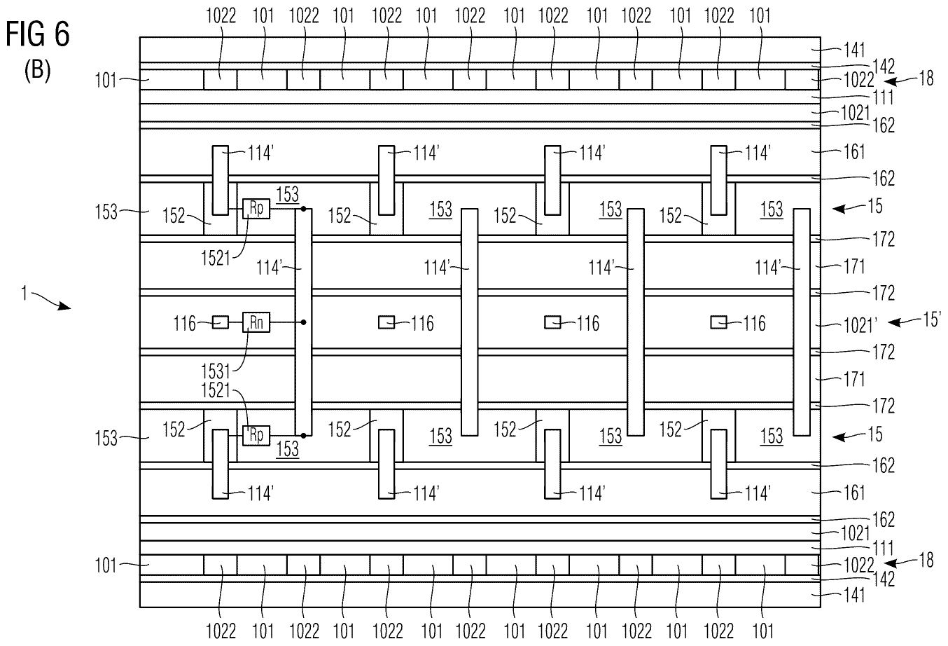

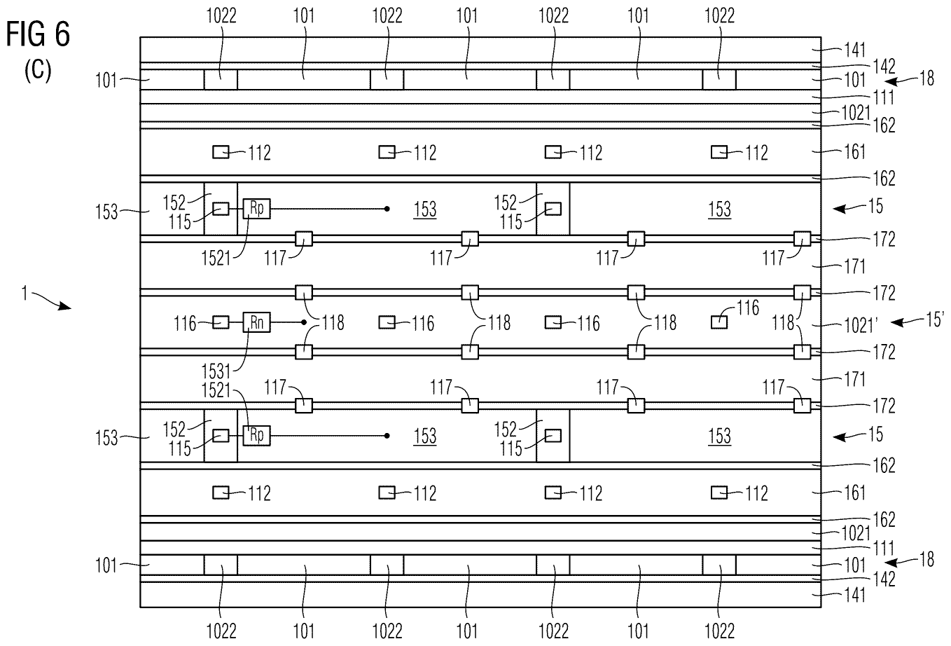

FIG. 6(A) illustrates a horizontal projection corresponding to the embodiment illustrated in FIG. 5, wherein the left part of the trench-mesa-pattern of FIG. 5 is mirrored at a vertical central axis of the third type mesa 15′.

It is noted that for dimensioning the resistance of first ohmic resistor 1531 and the resistance of the second ohmic resistor 1521, the resistance of the third region 153 and the resistance of the second region 152 may also be considered, as these resistances contribute to the total resistance of first ohmic resistor 1531 and the total resistance of the second ohmic resistor 1521, in accordance with an embodiment.

FIG. 6(B) illustrates a variant of the embodiment of FIG. 6(A), wherein shared contact bridges 114′ are employed to connect the respective regions. For example, some of the shared contact bridges 114′ contact the third regions 153 of the two second type mesas 15, the trench electrodes 171 of the two third type trenches 17 and the second body region 102′ or, respectively, its optional highly doped subportion 1021′. Others of the shared contact bridges 114′ contact one of the second regions 152 and one of the source trench electrodes 161.

FIG. 6(B) also illustrates that the pitch of the structures in the first type mesas 18 in the second lateral direction Y may be different from the pitch of the structures in the second type mesas 15.

FIG. 6(C) illustrates a further variant of the embodiment of FIG. 6(A) where a different lateral structure of the third regions 153 and the second regions 152 in the second type mesas 15 is proposed. Accordingly, the total lateral extension of the second region 152 along the second lateral direction Y is decreased and the total lateral extension of the third region 153 along the second lateral direction Y is correspondingly increased.

Here, it is emphasized that the both the structure of the semiconductor regions in the second type mesas 15 and the contacting scheme for the second type mesas 15 are independent from the structure of the semiconductor regions in the first type mesas 18 and the contacting scheme for the first type mesas 18, respectively, in accordance with an embodiment.

In accordance with the embodiments illustrated in FIGS. 7(A) and 7(B), the third region 153 is coupled to the first load terminal 11 by a Zener diode 1533. Except for the coupling of the third region 153 with the first load terminal 11, this and the subsequently described embodiments may correspond to the embodiments described with respect to FIGS. 1 to 6(c), such it is referred to the above.

For example, referring to both variants of FIGS. 7(A) and 7(B), based on the third region 153 (acting as n-emitter), the second region 152 (acting as p-base) and the first region 151 (acting as n-collector) an npn-transistor is integrated, wherein the third region 153 is initially floating. When turning-off overcurrent in the device 1, the third region 153 emits electrons due to the breakthrough of the Zener diode 1533 (also referred to as avalanche diode). The breakthrough of the Zener diode 1533 electrically connects the third region 153 to the first load terminal 11. Then, even if the control signal supplied to the control trench electrode 141 is an OFF-signal to cut-off the inversion channel in the body region 102, electrons are injected, leading to a reduced risk of a dynamic avalanche, as explained in more detail with respect to FIG. 1.

In an embodiment, the breakthrough voltage of the Zener diode 1533 is within the range of 3 V to 20 V, e.g. between 5 V and 10 V.

In an embodiment, as illustrated in the variant of FIG. 7(B), the third region 153 is coupled to the first load terminal 11 based on a series connection of a third ohmic resistor 1534 and the Zener diode 1533.

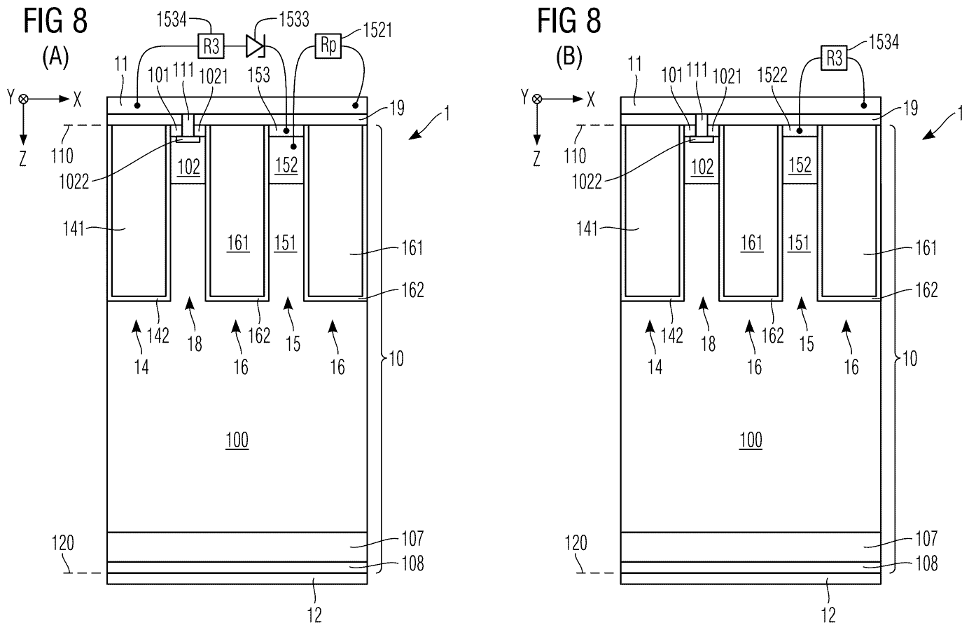

Furthermore, the second region 152 may be connected to the first load terminal 11 based on the second ohmic resistor 1521, cf. FIGS. 8(A) and 8(B), according to the variants illustrated in FIGS. 7(A) and 7(B). As explained with respect to FIGS. 6(A) to 6(C), the third region 153 and the second region 152 in the second type mesa 15 may be laterally structured along the second lateral direction Y. FIGS. 8(A) and 8(B) illustrate different positions along the second lateral direction Y.

It is noted that, in accordance with an embodiment, both the second regions 152 in the second type mesas 15 and the body regions 102 in the first type mesas 18 may be produced based on joint processing steps. Accordingly, both the second regions 152 in the second type mesas 15 and the body regions 102 in the first type mesas 18 may exhibit the same vertical extension. Furthermore, as body regions 102, the second regions 152 may exhibit highly doped subregions 1522. Likewise, in an embodiment both the third regions 153 in the second type mesas 15 and the source regions 101 in the first type mesas 18 may be produced based on joint processing steps. Accordingly, both the third regions 153 in the second type mesas 15 and the source regions 101 in the first type mesas 18 may exhibit the same vertical extension.

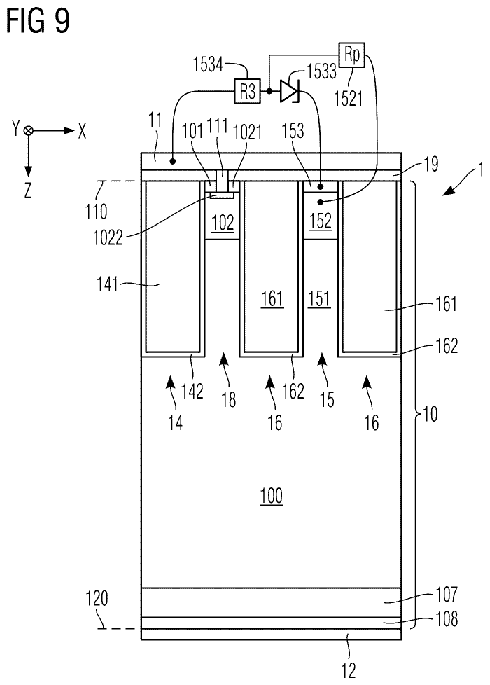

According to the embodiment illustrated in FIG. 9, the second region 152 is indirectly connected to the first load terminal 11 via the second ohmic resistor 1521 and the third ohmic resistor 1534.

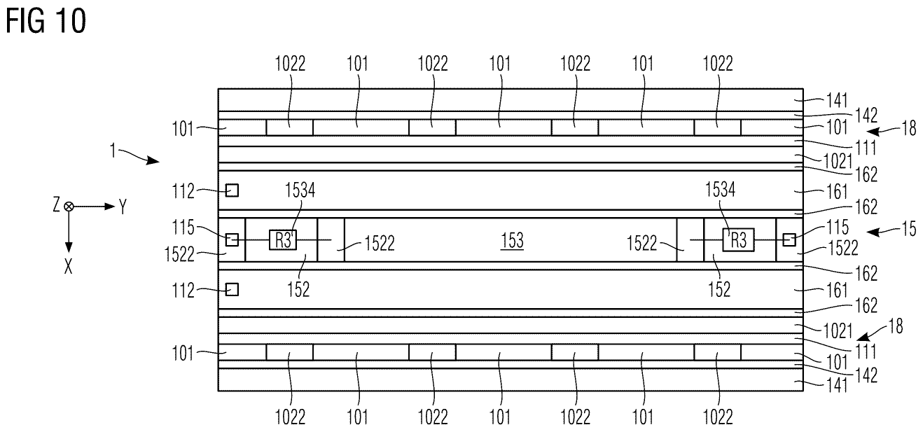

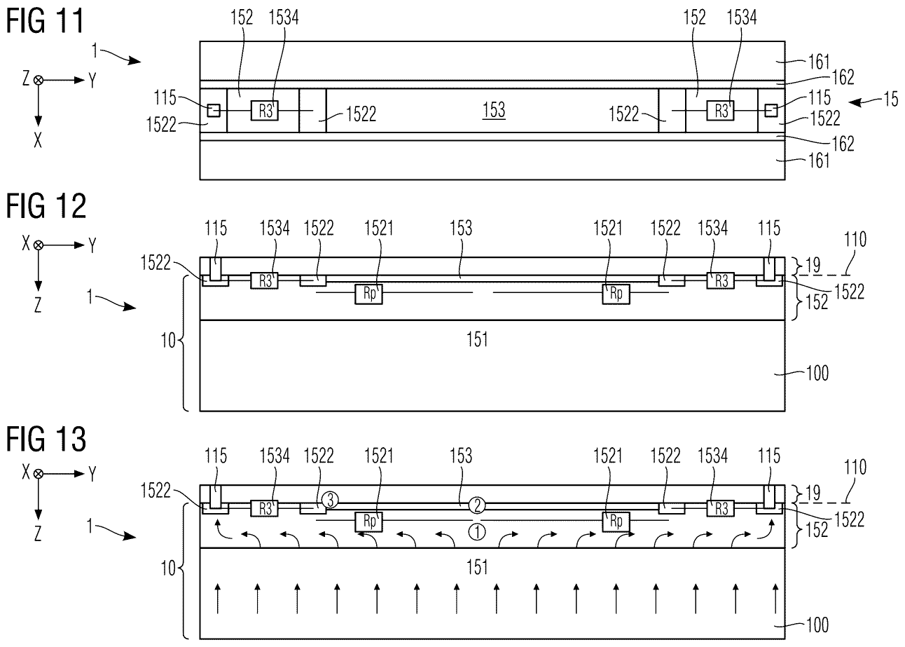

FIG. 10 schematically illustrates a horizontal projection of an embodiment corresponding to FIGS. 7(A), 7(B), 8(A), 8(B) and 9. The second type mesa 15, which is also illustrated in FIG. 11, and which includes the semiconductor structure 151, 152, 153 is arranged between two source trenches 16, each of which being arranged next to an adjacent one of the first type mesas 18. Of course, this trench-mesa-pattern is exemplarily described; other trench-mesa-patterns may be chosen.

As described above, e.g., with respect to FIGS. 6(A)-(C), the second contact plugs 112 electrically connect the source trench electrodes 161 with the first load terminal 11. The third contact plugs 115 electrically connect the second regions 152 (or, respectively, their highly doped subregions 1522) with the first load terminal 11.

The Zener diode 1533 is for example formed based on a pn-junction formed at a transition (along the second lateral direction Y) between the third region 153 and the highly doped subportion 1522 of the second region 152. The third ohmic resistance 1534 may be formed via a less doped region in the second the type mesa 15, e.g., based on the second region 152. The second region 152 may be connected to the first load terminal 11 via one of said third contact plugs 115, which extends into a further highly doped subportion 1522 of the second region 152 or directly into the second region 152. The highly doped subportion 1522 and the further highly doped subportion 1522 may together form a continuous region.

FIG. 11 shows the portion of FIG. 10 including the second type mesa 15 and the adjacent source trenches 16. FIG. 12 illustrates a vertical cross-section corresponding to the horizontal projection in FIG. 11. For example, two laterally displaced highly doped subportions 1522 of the second region 152 are each contacted by one of the third contact plugs 115. Two further highly doped subportions 1522 arranged separately from these contacted highly doped subportions 1522 adjoin the first region 153. Again, it is noted that the respective two subportions 1522 (connected by the respective third ohmic resistances R3) may alternatively form a single contiguous subportion 1522. In either case, the subportions 1522 are separated from each other based on the third region 153, wherein the third region 153 may over-compensate the subportions 1522.

The highly doped subportions 1522 of the second region 152 in the second type mesas 15 may be formed based on an implantation processing step. The same or another implantation processing step may be employed for forming the highly doped subportions of the body regions 102 in the first type mesas 18. The implantation for the highly doped subportions 1522 also may reach the location of the first region 153 or part of it. In this case the first region 153 may overcompensate the implantation there. This process can for example be advantageous for an embodiment described below with respect to FIG. 15.

Based on FIG. 13, which corresponds to FIG. 12 and additionally illustrates the path of a part of the load current, an exemplary function of the semiconductor structure in the second type mesa 15 shall be explained:

During switching the device 1 from the forward conducting state to the forward blocking state, a significant part of the load current flows as hole current towards the first side 110. A part of this current flows into the second type mesa 15 and there in the second region 152 (e.g., p-base region) laterally further to the next third contact plug 115. The voltage drop across the second ohmic resistor 1521 (Rp) leads to an increase of the potential of the second region at point 1, for example to about 10 V. There, the pn-junction to the third region 153 (e.g., n-emitter region) is initially only slightly poled in the forward direction, so that at point 2 in the third region 153 there is also a potential of about 10 V (more precisely a little less, about 9.5 V). This potential is also present at point 3 in the third region 153, while in the adjacent highly doped subportion 1522 of the second region 152, the potential is lower (close to 0 V). At point 3, the pn-junction of the Zener diode 1533 is hence reversely biased. If this voltage drop across the pn-junction of the Zener diode 1533 exceeds the breakdown voltage of the Zener diode 1533, electron-hole pairs are generated at point 3. The generated electrons then flow in the third region 153 (n-emitter region) towards point 2 and are there injected into the second region 152 (p-basis region). These electrons then continue to flow into the space charge region and there in the high electric field region towards the second side 120. As explained above, in the high electric field strength region of the space charge zone, electrons and holes flow with a velocity that is close to their respective saturation velocity. Hence theirs concentrations are approximately proportional to the respective current densities. The injected electron current thus leads to a negative contribution to the space charge density and compensates at least in part the positive contribution made by the charge of the holes. Due to the diminished total space charge density a reduced gradient of the electric field and an accordingly reduced maximum field strength is achieved.

Regarding the embodiments where the third region 153 is coupled to the first load terminal 11 via at least said Zener diode 1533, one or more of the following dimensioning rules (vi) to (viii) may apply:
(vi) The parallel connection of all second ohmic resistors 1521 exhibits a product of active area times resistance, Rp*Aact, of at least 10 mOhmcm² or of at least 0.1 Ohmcm².
(vii) The parallel connection of all third ohmic resistors 1534 exhibits a product of active area times resistance, R3*Aact, within the range of 0.2 mOhmcm² to 100 mOhmcm² or within the range of 1 mOhmcm² to 10 mOhmcm².
(viii) Dimensioning rules (vi) and (vii) may be suitable in case of the device 1 having a nominal load current density in the range of 200 A/cm². If the nominal current density jnom deviates significantly from 200 A/cm², the values given in rules (vi) and (vii) should be scaled anti-proportionally to the nominal current density. For example, Rp*Aact then amounts to at least 2 V/jnom or at least 20 V/jnom. And, R3*Aact is then between 0.04 V/jnom and 20 V/jnom or between 0.2 V/jnom and 2 V/jnom. These values apply at room temperature and can vary depending on the temperature, e.g., increase slightly with higher temperature.

With respect to the formation of the third ohmic resistor 1534 (R3) and the second ohmic resistor 1521 (Rp) (when provided in an embodiment where the third region 153 is coupled to the first load terminal 11 via at least said Zener diode 1533), a few examples will now be described referring to the next Figures.

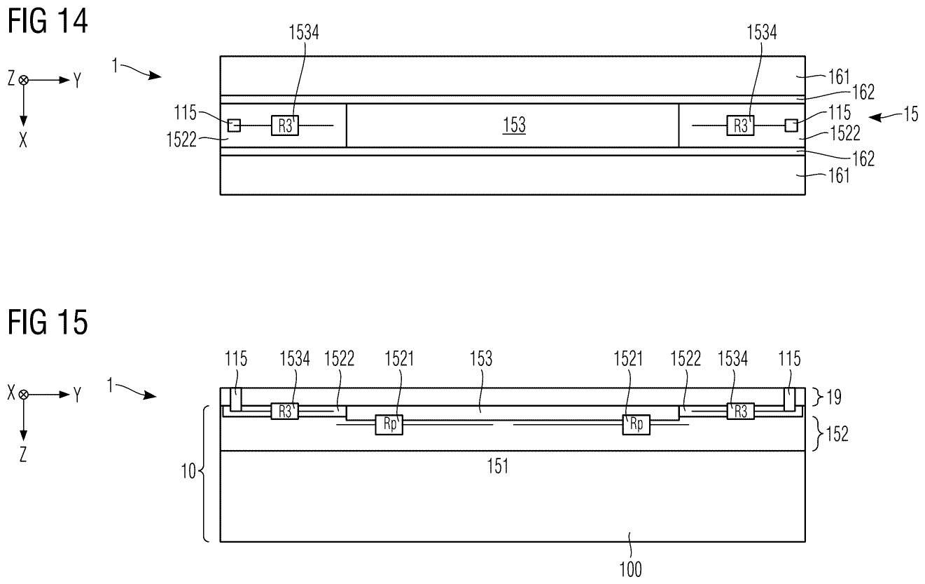

As explained above, in an embodiment, a significant portion of the total resistance of the third ohmic resistor 1534 is formed by the second region 152 and/or by one or more of the high doped subportions 1522 of the second region 152, the latter variant of the embodiment illustrated in FIGS. 11 and 12 being illustrated in FIGS. 14 and 15, where the highly doped subportions 1522 uninterruptedly couple the third region 153 to the third contact plugs 115. As explained above, the third region 153 (of the first conductivity type) may over-compensate the subportions 1522 (of the second conductivity type). To achieve this effect, in an embodiment and as illustrated in FIG. 15, the third region 153 may extend further along the vertical direction Z than the subportions 1522 of the second region 152. For example, such configuration may yield advantages in terms of producing the device 1, as for example the highly doped subportions 1522 may be implanted without employing a mask before the third region 153 is implanted with a mask. Additionally or alternatively, the lateral extension of the region 1522 and 153 may be chosen such that the third region 153 (of the first conductivity type) over-compensates the subportions 1522 (of the second conductivity type) in an overlapping region.

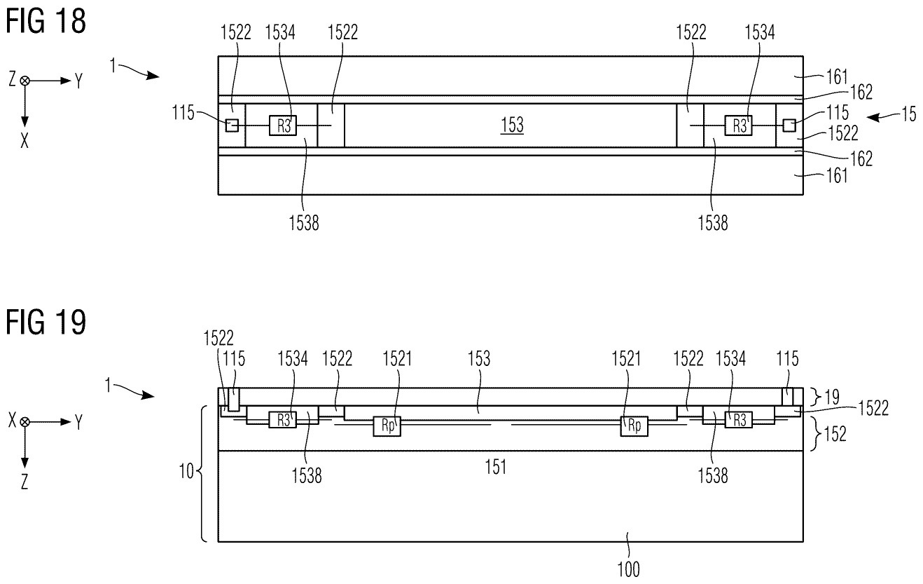

A yet further variant is illustrated in FIGS. 18-19. In FIGS. 18-19, the path between the highly doped subportion 1522 being contacted by the third contact plug 115 and the highly doped subportion 1522 being contacted by the third region 153 includes a further region 1538 of the first conductivity type. The further region 1538 of the first conductivity type may be a floating region. The further region 1538 of the first conductivity type may exhibit the same dopant concentration as the third region 153, but a smaller total lateral extension along the second lateral direction Y, e.g., amounting to less than half of the total lateral extension of the third region 153 along the second lateral direction Y, e.g., so as to avoid that the further region 1538 of the first conductivity type acts as emitter region. The further region 1538 of the first conductivity type may over-compensate the subportions 1522 (of the second conductivity type), e.g., such that the third ohmic resistance 1534 consists only of a part of the second region 152 below the further region 1538 of the first conductivity and thus has a correspondingly increased resistance value.

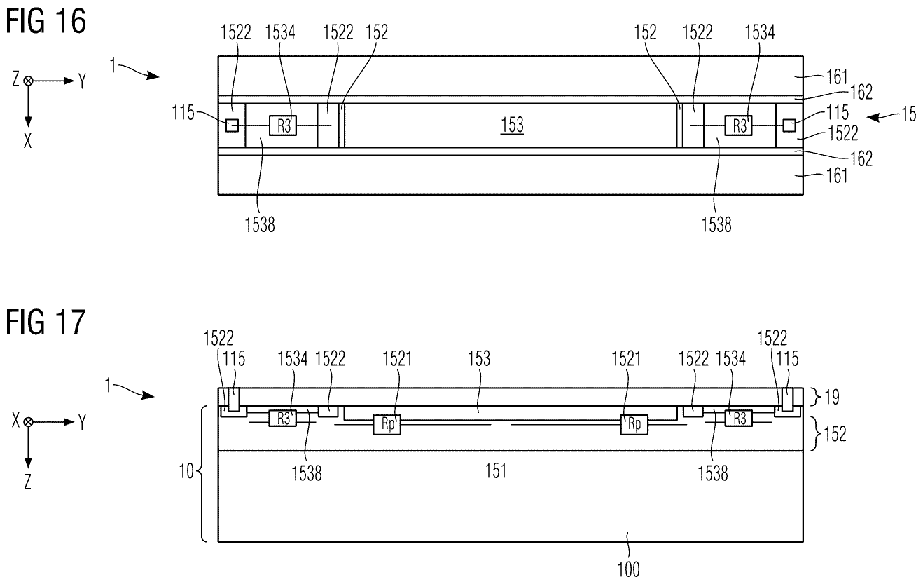

The third region 153 may may be arranged in contact with the adjacent two highly doped subportions 1522 (as illustrated e.g. in FIGS. 12 and 13) or spaced apart therefrom (as illustrated in FIGS. 16 and 17). Via the (possible) distance between the third region 153 and the highly doped subportion 1522 adjacent to the third region 153, the breakthrough voltage of the Zener diode 1533 may be influenced.

In an embodiment, the total extension of the region corresponding to the third ohmic resistor 1534 (e.g. the further region 1538 of the first conductivity type or the distance between the highly doped subportions 1522) is within the range of 0.5 μm to 20 μm. Further, the total extension of the third region 153 can be within the range of 5 μm to 100 μm. The exact values may be chosen in dependence of the designated resistance R3 of the third ohmic resistor 1534 and the designated resistance Rp of the second ohmic resistor 1521.

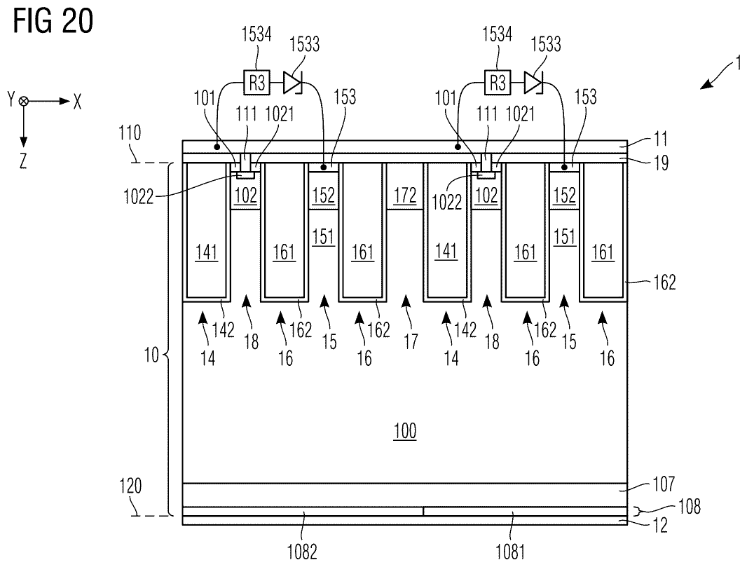

The above presented embodiments of including the semiconductor structures 151, 152, 153 in the second type mesas 15 may be used in devices where the emitter region 108 at the second side 120 is laterally structured, as shown in FIG. 20.

For example, the emitter region 108 includes one or more first subregions 1081 and one or more second subregions 1082 that differ in average dopant concentration and/or in emitter efficiency. Said difference in dopant concentrations of the emitter region 108 at the second side 120 may be reflected by a corresponding alteration of the dimensioning of the breakthrough voltage of the Zener diode 1533 and/or the resistance of the third ohmic resistor 1534 and/or the resistance of the second ohmic resistor 1521. For example, in a region laterally overlapping with an increased emitter efficiency (for example the first subregion 1081), the resistance R3 of the third ohmic resistor 1534 is higher as compared to in a region laterally overlapping with a decreased emitter efficiency (for example the second subregion 1082).

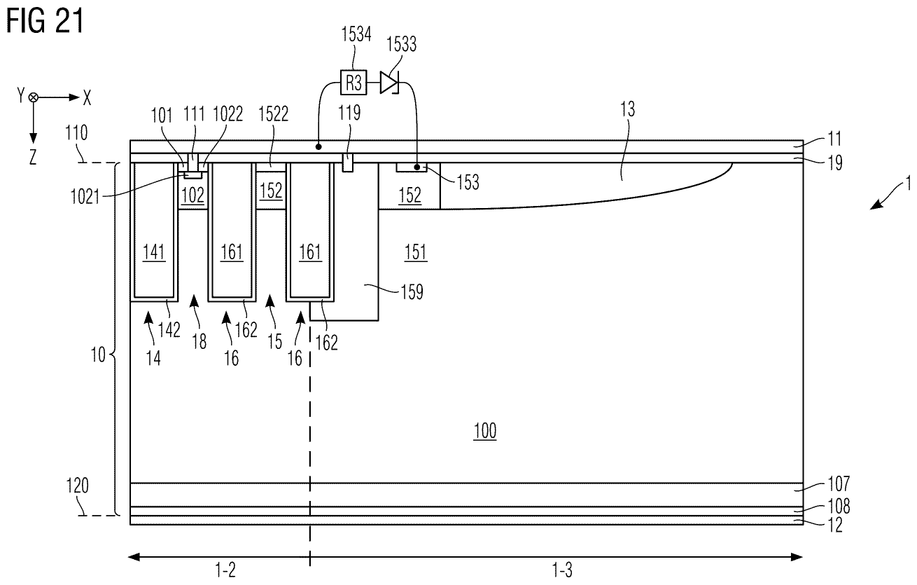

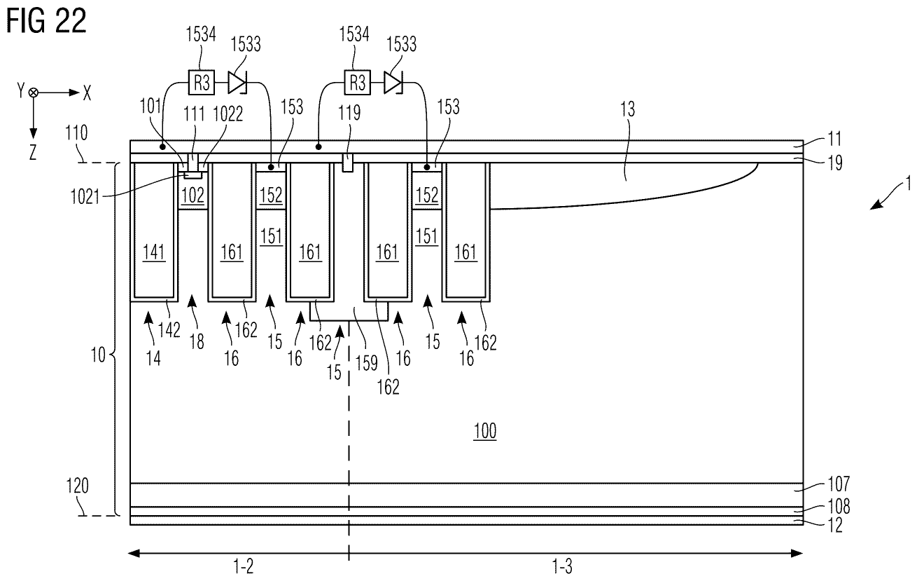

As illustrated in FIGS. 21-22, e.g., due to higher current densities during turn-off in the region close to the junction termination, the semiconductor structures 151, 152, 153 may exclusively be arranged in or close to an edge termination region 1-3 surrounding an active region 1-2 (which includes a cell field comprising in particular the first type mesas 18 and the control trenches 14), cf. FIG. 21, or in both the active region 1-2 and the edge termination region 1-3, cf. FIG. 22. For example, referring to FIG. 21, the semiconductor structure 151, 152, 153 is not necessarily arranged in one of the second type mesas 15, but adjacent to one of the source trenches 16 at a transition between the active region 1-2 and the edge termination region 1-3. There, the second region 152 may laterally adjoin a well region 13 of the second conductivity type. At the other side, a region of the second conductivity type 159, e.g., a so-called p-ring, adjacent to the second region 152 may laterally be connected to the first load terminal 11 via one or more further contact plugs 119. In another embodiment, as illustrated in FIG. 22, the semiconductor structure 151, 152, 153 is arranged in one of the second type mesas 15 in the edge termination region 1-3. The third ohmic resistance 1534 can be connected to the first load terminal 11 via a (in FIGS. 21-22 non-illustrated) contact, e.g., arranged in the rightmost mesa 15.

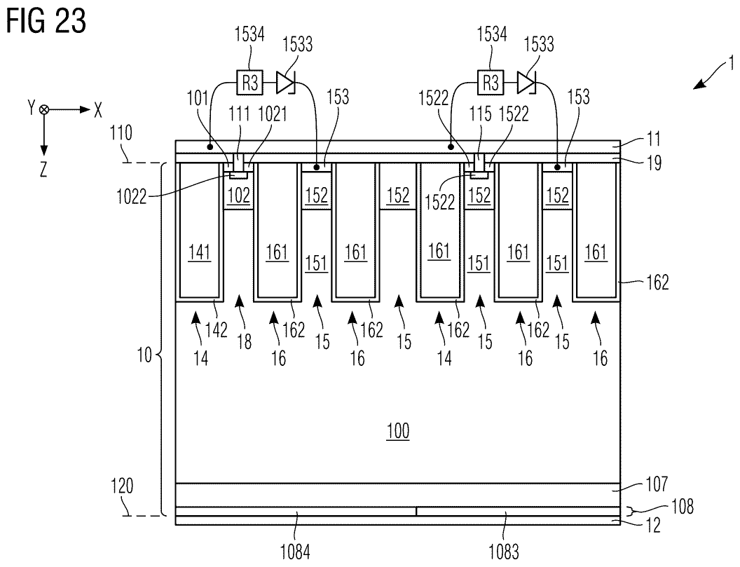

If the device 1 is embodied as an RC IGBT, the semiconductor structures 151, 152, 153 may be arranged in both the IGBT region of the RC IGBT and the diode region of the RC IGBT. For example, referring to FIG. 23, the emitter region 108 includes one or more first sections 1083 and one or more second sections 1084 that differ in dopant type. For example, the one or more first sections 1083 are part of the IGBT region and hence of the second conductivity type. The one or more second sections 1084 are part of the diode region and hence of the first conductivity type. Said difference in dopant type of the emitter region 108 at the second side 120 may be reflected by a corresponding alteration of the dimensioning of the breakthrough voltage of the Zener diode 1533 and/or the resistance of the third ohmic resistor 1534. For example, in a region part of the diode region (laterally overlapping with the one or more second sections 1084), the resistance R3 of the third ohmic resistor 1534 is higher or lower as compared to in a region part of the IGBT region (laterally overlapping with the one or more first sections 1084), because the current density in the diode region can be different from the current density in the IGBT region.

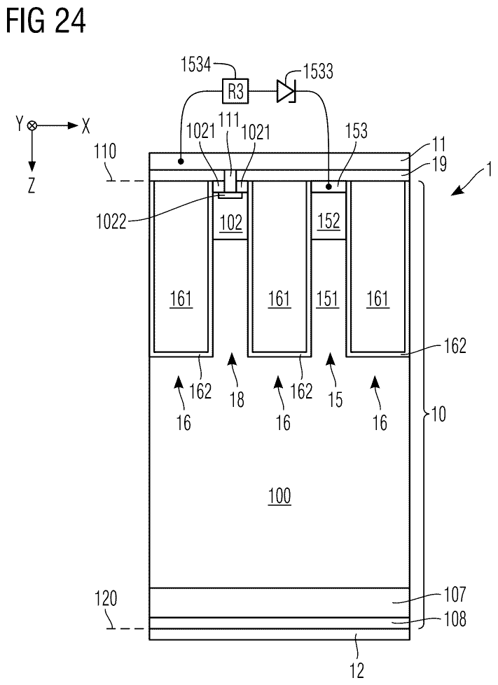

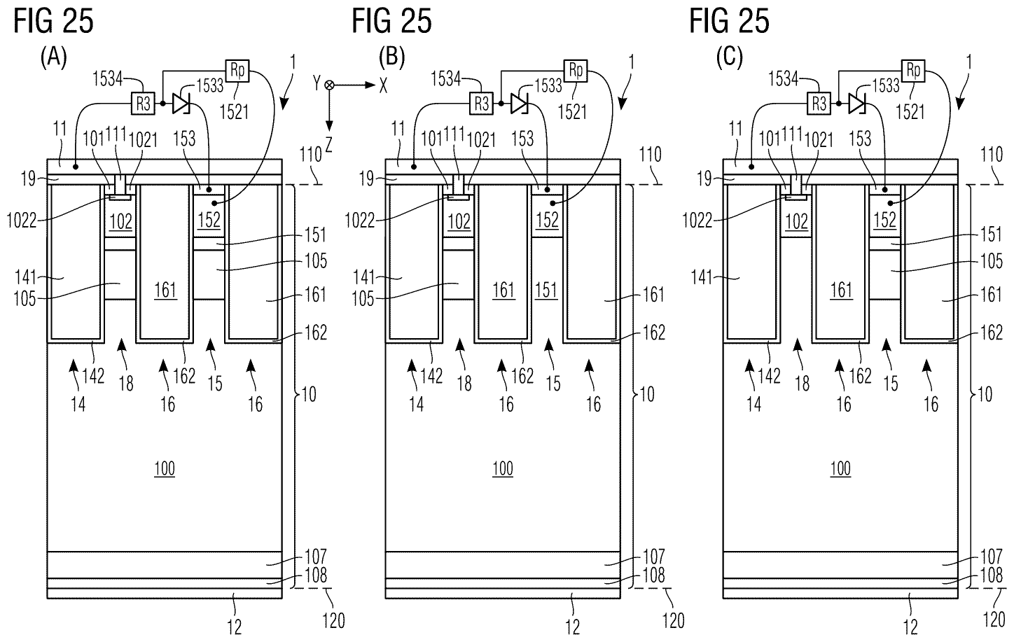

The device 1 may also be embodied as a diode, cf. FIG. 24, where the emitter region 108 is entirely of the first conductivity type. Then, there is no source region 101 included in the first type mesas 18. If embodied as a diode, the device 1 can be provided without trench electrodes.

FIGS. 25(1)-25(C) illustrate three variants of the embodiment of FIG. 9. According to these variants, the device 1 further includes a barrier region 105 of the first conductivity type. The barrier region 105 exhibits a greater dopant concentration as compared to the drift region. In an embodiment, cf. FIG. 25(A), the barrier region 105 is arranged in both the first type mesas 18 and the second type mesas 15. There, it may be arranged in contact with the body region 102 and the second region 152 or, as illustrated, spaced apart therefrom along the vertical direction Z. A lower surface of the barrier region 105 may still be arranged within the mesas 15, 18; i.e., the barrier region 105 does in an example not extend below the bottoms of the trenches 14, 16. Furthermore, the barrier region 105 may be laterally structured, e.g., in that it extends into only the first type mesas 18 (FIG. 25(B)) or into only the second type mesas 15 (FIG. 25(C)).

Furthermore, in another embodiment such structures can be implemented in areas, where the local doping of the backside emitter is enhanced, which can be the case for example to improve the softness of the device or to improve the current-induced short-circuit ruggedness.

Presented herein is also a method of producing a power semiconductor device. The method comprises forming, in a single chip, the following components: A semiconductor body configured to conduct a load current between a first load terminal at a first side of the semiconductor body and a second load terminal at a second side of the semiconductor body; a drift region of a first conductivity type within the semiconductor body; trenches extending from the first side towards the second side, each trench including a trench electrode separated from the semiconductor body by a trench insulator; mesas laterally confined by said trenches, wherein the mesas include first type mesas and second type mesas; and semiconductor structures. Each semiconductor structure includes a serial connection of a first region of the first conductivity type coupled to or formed by the drift region; a second region of a second conductivity type; and a third region of the first conductivity type coupled to the first load terminal by at least one of a first ohmic resistor and a Zener diode. Each first type mesa is configured for load current conduction, electrically connected to the first load terminal and devoid of any of said semiconductor structures. The semiconductor structures are arranged in the second type mesas.

Embodiments of this production method correspond to the embodiments of the power semiconductor device 1 described above. Accordingly, these embodiments of the method will not literally be described herein, but it is referred to the above. For example, as described, both the body regions 102 in the first type mesas 18 and the second regions 152 in the second type mesas 15 may be formed based on joint processing steps. Likewise, both the source regions 101 in the first type mesas 18 and the third regions 153 in the second type mesas 15 may be formed based on joint processing steps.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGalnN), indium gallium nitride (InGaN)-aluminum gallium indium nitride (AlGalnN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor device, comprising, in a single chip:
a semiconductor body configured to conduct a load current between a first load terminal at a first side of the semiconductor body and a second load terminal at a second side of the semiconductor body;
a drift region of a first conductivity type within the semiconductor body;
trenches extending from the first side towards the second side, each trench including a trench electrode separated from the semiconductor body by a trench insulator;
mesas laterally confined by the trenches, wherein the mesas include first type mesas and second type mesas;
semiconductor structures, wherein each semiconductor structure includes a serial connection of:
a first region of the first conductivity type coupled to or formed by the drift region;
a second region of a second conductivity type; and
a third region of the first conductivity type coupled to the first load terminal by at least one of a first ohmic resistor and a Zener diode;
wherein each first type mesa is configured for load current conduction, electrically connected to the first load terminal, and devoid of any of the semiconductor structures,
wherein the semiconductor structures are arranged in the second type mesas.

2. The power semiconductor device of claim 1, wherein the trenches include first type trenches, and wherein each trench electrode of the first type trenches is electrically insulated from the first load terminal and configured to receive a control signal.

3. The power semiconductor device of claim 2, wherein each first type mesa is laterally confined by at least one of the first type trenches.

4. The power semiconductor device of claim 1, wherein the trenches include second type trenches, and wherein each trench electrode of the second type trenches is electrically connected to the first load terminal.

5. The power semiconductor device of claim 4, wherein each second type mesa is laterally confined by at least one of the second type trenches.

6. The power semiconductor device of claim 4, wherein the trenches further include first type trenches, wherein each trench electrode of the first type trenches is electrically insulated from the first load terminal and configured to receive the control signal, and wherein each second type mesa is laterally confined by none of the first type trenches.

7. The power semiconductor device of claim 1, wherein the semiconductor structures are configured to inject electrons into the semiconductor body during an overload situation to limit the strength of an electric field in the semiconductor body.

8. The power semiconductor device of claim 1, wherein the semiconductor structures are configured not to inject a significant amount of electrons into the semiconductor body if the load current is equal to or less than a nominal load current of the power semiconductor device.

9. The power semiconductor device of claim 1, wherein the second region of at least one or of each of the semiconductor structures is coupled to the first load terminal by at least a second ohmic resistor.

10. The power semiconductor device of claim 9, wherein both the first ohmic resistor and the second ohmic resistor are integrated within the chip and in proximity to the respective semiconductor structure.

11. The power semiconductor device of claim 9, wherein both the first ohmic resistor and the second ohmic resistor are at least partially integrated within the one or more of the second type mesas.

12. The power semiconductor device of claim 1, wherein each of the semiconductor structures exhibits a vertical configuration according to which the serial connection is established along a direction pointing from the second side to the first side.

13. The power semiconductor device of claim 1, wherein each first type mesa comprises a semiconductor body region of the second conductivity type electrically connected to the first load terminal.

14. The power semiconductor device of claim 1, wherein each of the first region, the second region, and the third region of each semiconductor structure are arranged in the second type mesas.

15. The power semiconductor device of claim 1, wherein the third region is coupled to the first load terminal via the Zener diode and a third ohmic resistor.

16. The power semiconductor device of claim 1, wherein the second region comprises one or more highly doped subportions of the second conductivity type.

17. The power semiconductor device of claim 1, wherein the third region is arranged in contact with an insulation layer, the insulation layer being arranged between the first load terminal and the semiconductor body, and wherein the second region isolates the third region from a remaining portion of the semiconductor body.

18. The power semiconductor device of claim 1, wherein the third region is coupled to the first load terminal via the Zener diode and a third ohmic resistor, wherein the second region comprises one or more highly doped subportions of the second conductivity type, wherein the third region is arranged in contact with an insulation layer, the insulation layer being arranged between the first load terminal and the semiconductor body, wherein the second region isolates the third region from a remaining portion of the semiconductor body, wherein a pn-junction of the Zener diode is formed based on a transition between one of the highly doped subportions and the third region, and wherein the second region is connected with the first load terminal.

19. The power semiconductor device of claim 1, wherein the power semiconductor device is one of an IGBT, an RC IGBT or a diode.

20. A method of producing a power semiconductor device, the method comprising:
forming a semiconductor body in a chip, the semiconductor body configured to conduct a load current between a first load terminal at a first side of the semiconductor body and a second load terminal at a second side of the semiconductor body;
forming a drift region of a first conductivity type within the semiconductor body;
forming trenches extending from the first side towards the second side, each trench including a trench electrode separated from the semiconductor body by a trench insulator;
forming mesas laterally confined by the trenches, wherein the mesas include first type mesas and second type mesas;
forming semiconductor structures, wherein each semiconductor structure includes a serial connection of:
a first region of the first conductivity type coupled to or formed by the drift region;
a second region of a second conductivity type; and
a third region of the first conductivity type coupled to the first load terminal by at least one of a first ohmic resistor and a Zener diode;
wherein each first type mesa is configured for load current conduction, electrically connected to the first load terminal, and devoid of any of the semiconductor structures,
wherein the semiconductor structures are arranged in the second type mesas.
